(19) United States
(12) Patent Application Publication
(10) Pub. No.: US 2005/0025318 A1
(43) Pub. Date: Feb. 3, 2005

(54) Reproduction system for video and audio signals

(76) Inventors: Koichi Sadaie, Osaka (JP); Tetsuro Nakatake, Osaka (JP); Noboru Honjo, Osaka (JP)

Correspondence Address: MARK D. SARALINO (GENERAL);RENNER, OTTO, BOISELLE & SKLAR, LLP, 1621 EUCLID AVENUE, NINETEENTH FLOOR, CLEVELAND, OH, 44115-2191, US

(21) Appl. No.: 10/894,227

(22) Filed: Jul. 19, 2004

(30) Foreign Application Priority Data
Jul. 31, 2003 (JP) 2003-283463

(51) Int. Cl. H04R 5/00; H03G 3/00

(52) U.S. Cl. 381/63; 381/160; 181/191

(57) ABSTRACT

A reproduction system includes speaker array composed of plural speakers having a diaphragm for reproducing an audio signal and reflection unit disposed in a chamber for reflecting a radiated sound from the speaker array. The plural speakers of the speaker array are positioned so that the vibration direction of each diaphragm may be directed towards the reflection unit, and the reflection path distance from each diaphragm to a listening point, which defines a position of the viewer/listener, via the reflection surface of the reflection unit may be equal.

### BACKGROUND OF THE INVENTION

1. Field of the Invention

The present invention relates to a reproduction system for reproducing an audio signal or to a reproduction system for reproducing synchronized video and audio signals.

2. Description of the Related Art

In a reproduction system such as a stereo or AV system, an audio signal or synchronized video and audio signals are reproduced to a viewer/listener with a speaker, display, screen, or the like disposed in a chamber. At this time, the display or screen may be disposed on a wall surface, and the speaker used for reproduction of the audio signal may be disposed on a wall surface or ceiling. In these cases, when the speaker is disposed on a ceiling in particular, there is a problem of lacking in the sense of integration because, for the viewer/listener, the direction of projecting the video signal is different from the direction of an arriving audio signal.

FIG. 6 is a view describing a reproduction system according to the conventional art. Speaker array 10 disposed on ceiling 102 of chamber 101 is located above a viewer/listener 100, and is composed of plural (eight in FIG. 6) speakers 11 to 18, which are respectively connected to delay circuits 21 to 28 and level controlling circuits 31 to 38. By setting the delay time and level of these, speaker array 10 controls the radiation directivity characteristics, whereby the main beam of the radiated sound can be directed towards wall surface 103 of chamber 101. As a result of this, viewer/listener 100 obtains an audio image localization by the acoustic wave reflected at wall surface 103, so that viewer/listener 100 feels that the audio signal is being reproduced not in the direction of speaker array 10 (above) but in the direction of wall surface 103 (front). This is due to the following reason. Since for the viewer/listener 100, the reflected sound (RS) from wall surface 103 has a higher level than the direct sound (DS) from speaker array 10, and the delay of reflected sound RS relative to direct sound DS is within the time that produces the Haas effect, the viewer/listener 100 obtains the sense of localization not from direct sound DS but from reflected sound RS.

Therefore, when a video signal and an audio signal are reproduced at the same time, the front localization of video images coincides with that of audio images. For example, a reproduction apparatus 40 that reproduces synchronized video signal V and audio signal A can set the localizations of video images and audio images in the front by outputting the video signal V to projection unit 41 to project the video signal V onto screen 42 disposed on wall surface 103 and reproducing the audio signal A with speaker array 10.

However, the reproduction system according to the conventional art requires complex delay circuits and level controlling circuits, raising a problem of difficulty in realizing the system at a low cost. Though the plural speakers in speaker array 10 are preferably large in number, it has been unrealistic to dispose and adjust a delay circuit and level controlling circuit in each speaker. When the audio signal is made of plural channels such as in a stereo signal or a multi-channel signal, the system has needed a further larger size.

In addition, in the reproduction system according to the conventional art, in the case of reproducing synchronized video and audio signals, a large delay of about 5 to 40 msec occurs in order that the radiated sound from speaker array 10 is reflected by wall surface 103 and reaches viewer/listener 100. Therefore, the video signal and the audio signal are reproduced with lost synchronization of video images and audio images, thereby raising a problem of causing a reproduction state that gives viewer/listener 100 a sense of discordance.

### SUMMARY OF THE INVENTION

The present invention has been made in order to solve the aforementioned problem of the conventional art, and an object thereof is to provide a reproduction system capable of front localization easily and at a low cost even in a representative case of disposing a speaker array on a ceiling in a chamber, and to provide a reproduction system capable of performing a good reproduction with synchronized video and audio images.

A reproduction system according to the present invention is a reproduction system for reproducing an audio signal to a viewer/listener in a chamber. The reproduction system includes speaker array composed of plural speakers having a diaphragm for reproducing the audio signal, and reflection unit disposed in the chamber for reflecting a radiated sound from the speaker array, wherein the plural speakers of the speaker array are positioned so that a vibration direction of each diaphragm may be directed towards the reflection unit, and a reflection path distance from each diaphragm to a listening point, which defines a position of the viewer/listener, via a reflection surface of the reflection unit may be equal.

Hereafter, the functions of the present invention will be described.

In a reproduction system according to the present invention, the plural speakers of the speaker array are each positioned as follows. Namely, a vibration direction of the diaphragm of each speaker is directed towards the reflection unit, and a reflection path distance from each diaphragm to a listening point, which defines a position of the viewer/listener, via a reflection surface of the reflection unit is made equal. Therefore, the radiated sounds reflected by the reflection surface (hereafter referred to as reflected sounds) are concentrated to and arrive at the listening point at the same time, so that the synthesized level of the reflected sounds will be greater than that of the direct sound, and the listener can perceive the direction of the arriving reflected sounds as an audio image localization direction. Even in the case of controlling the radiation directivity characteristics of the speaker array with a reproduction system of the conventional art, the synthesized level of the reflected sounds can be made larger than that of the direct sound; however, in the reproduction system according to the present invention, the increase in the synthesized level of the reflected sounds at the listening point can be made further more conspicuous. In the case of controlling the radiation directivity characteristics, it is difficult to provide a listening point to which the reflected sounds are concentrated. In contrast, in the reproduction system according to the present invention, it suffices only if the vibration direction of the diaphragm and the reflection path distance are equally set. Furthermore, the reproduction system according to the present invention eliminates the need for the delay circuit and the level controlling circuit that are needed in controlling the radiation directivity characteristics.

In a reproduction system according to a preferable embodiment of the present invention, the plural speakers of the speaker array are divided into plural sets corresponding to plural listening points. Therefore, in the reproduction system of the invention, even if there are plural viewers/listeners, each viewer/listener can obtain an audio image localization.

A reproduction system according to a preferable embodiment of the present invention includes speaker array and reflection unit corresponding to channel signals of the audio signal. Therefore, the viewer/listener can obtain an audio image localization of each channel signal in the direction of the reflection unit.

A reproduction system according to a preferable embodiment of the present invention is a reproduction system for reproducing synchronized video and audio signals to the viewer/listener in the chamber, further including projection unit for projecting the video signal and a projection surface disposed in the chamber.

In a reproduction system according to a preferable embodiment of the present invention, the reflection surface of the aforesaid reflection unit and the projection surface are integrally constructed and disposed in the chamber. Therefore, for the viewer/listener, the localization of video images and the localization of audio images can be made to coincide with each other in the front.

In a reproduction system according to a preferable embodiment of the present invention, the aforesaid projection unit includes a video delay circuit for delaying the video signal projected onto the projection surface, and a delay time of the video delay circuit is set to be approximately equal to a time required for an acoustic wave to propagate through the reflection path distance. Therefore, no time lag is present between the reproduction of video images and the reproduction of audio images, so that there will be no reproduction state that gives viewer/listener 100 a sense of discordance.

A reproduction system according to a preferable embodiment of the present invention further includes a video delay circuit for delaying the video signal or an audio delay circuit for delaying the audio signal, and a delay time of the video delay circuit or the audio delay circuit is set to maintain synchronization of the video signal and the audio signal in accordance with a time required for processing the video signal and a time required for an acoustic wave to propagate through the reflection path distance. Therefore, even if the time required for processing the video signal is long, no time lag will be present between the reproduction of video images and the reproduction of audio images for the viewer/listener.

### BRIEF DESCRIPTION OF THE DRAWINGS

FIG. 1 is a side cross-sectional view describing a reproduction system of the present invention (Embodiment 1)

FIG. 2 is a plan view describing a reproduction system of the present invention (Embodiment 1);

FIG. 3 is a plan view describing another reproduction system of the present invention (Embodiment 2);

FIG. 4 is a plan view describing another reproduction system of the present invention (Embodiment 3);

FIG. 5 is a side cross-sectional view describing another reproduction system of the present invention (Embodiment 4); and

FIG. 6 is a side cross-sectional view describing a reproduction system of the conventional art.

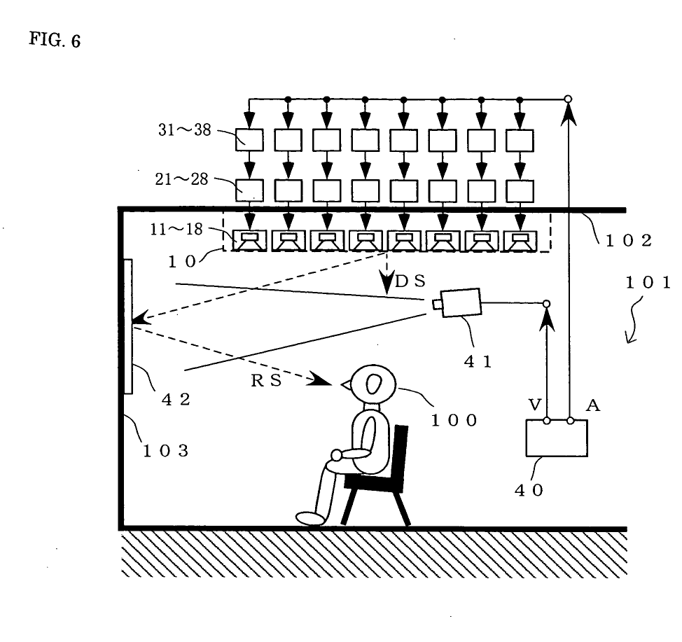

### DETAILED DESCRIPTION OF THE PREFERRED EMBODIMENTS

Hereafter, a reproduction system for video and audio signals according to the preferred embodiments of the present invention will be described; however, the present invention is not limited to these embodiments.

In a reproduction system for video and audio signals according to the present invention, an object of providing a reproduction state that gives a sense of integration with coincident localizations of video images and audio images easily and at a low cost is achieved without providing numerous delay circuits and level controlling circuits, by positioning the plural speakers of the speaker array so that a vibration direction of each diaphragm may be directed towards the reflection unit, and a reflection path distance from each diaphragm to a listening point, which defines a position of the viewer/listener, via a reflection surface of the reflection unit may be equal.

[Embodiment 1]

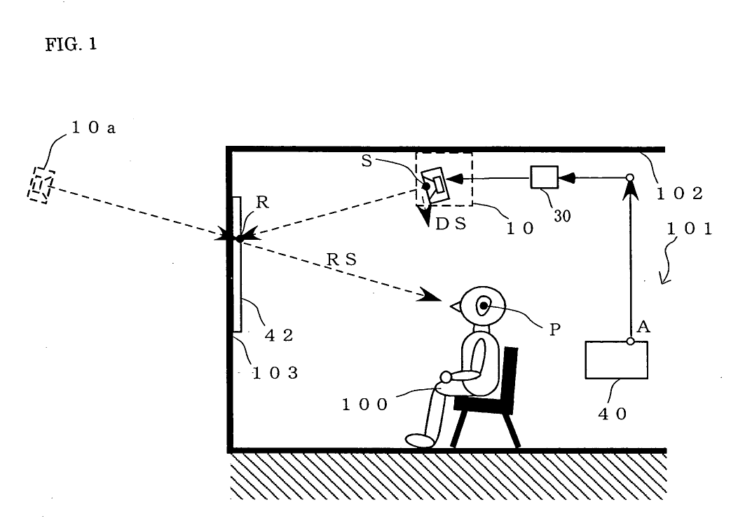

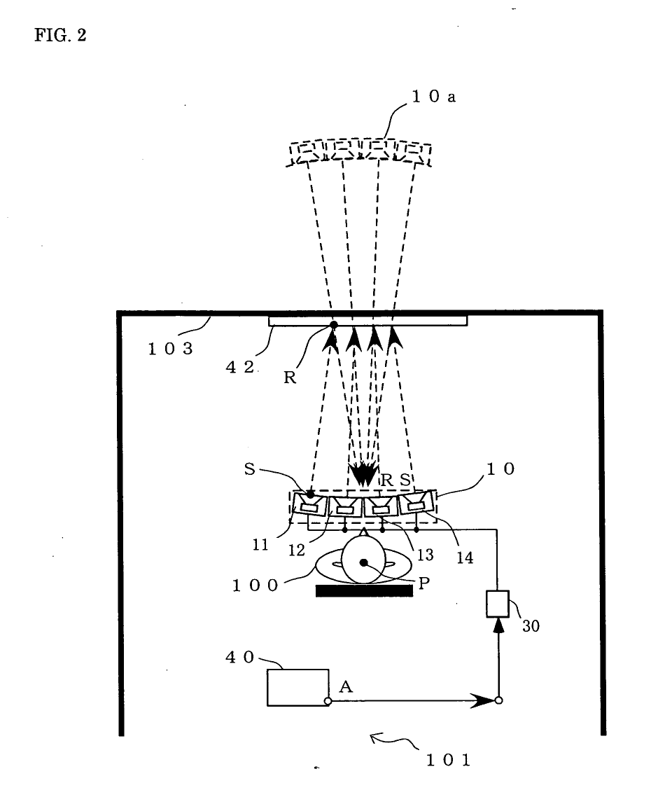

FIGS. 1 and 2 are views describing a reproduction system for an audio signal according to a preferable embodiment of the present invention. FIG. 1 is a side cross-sectional view of chamber 101, and FIG. 2 is a plan view of chamber 101. A speaker array 10 is disposed on a ceiling 102 above a viewer/listener 100 who is located at a listening point P within chamber 101. Reflection unit 42 is disposed on a wall surface 103 in the front. An audio signal A reproduced from a reproduction apparatus 40 passes through an amplifier 30 to be input into speaker array 10. Speaker array 10 is constructed with parallel connection of four speakers 11 to 14 having a diaphragm. Here, reproduction apparatus 40 may be representatively a visual acoustic apparatus such as a CD or DVD player.

In a reproduction system according to the present invention, the vibration direction of diaphragm S of each of the four speakers 11 to 14 of speaker array 10 is directed towards reflection unit 42, and the reflected sound RS is reflected towards listening point P. Moreover, a reflection path distance from diaphragm S of each of the four speakers 11 to 14 to listening point P, which defines a position of viewer/listener 100, via the reflection surface of reflection unit 42 is set to be equal. Here, the reflection path distance in FIGS. 1 and 2 is a sum of the distance from diaphragm S to reflection unit 42 and the distance from reflection point R to listening point P. Viewed from listening point P, the direction and position of plural speakers 11 to 14 of speaker array 10 are set so that the reflected sounds RS from the reflection surface of reflection unit 42 may be concentrated to and arrive at listening point P at the same time. In other words, disposing speaker array 10 at this position is equivalent to disposing a virtual speaker array 10a which is a mirror image (reflected image) of speaker array 10 with respect to the reflection surface of reflection unit 42 illustrated in FIGS. 1 and 2 and which is located away therefrom by the reflection path distance.

Therefore, at listening point P, the increase in the synthesized level of reflected sound RS can be made conspicuous as compared with that of direct sound DS. As a result of this, viewer/listener 100 can obtain an audio image localization in the direction of reflection unit 42 along which reflected sound RS arrives, even though speaker array 10 is disposed on ceiling 102.

Here, diaphragm S of each speaker in speaker array 10 may have an approximately identical shape, which may be any diaphragm shape such as a cone shape, plane shape, or dome shape. Further, the vibration direction of diaphragm S may be approximately equal to the direction that is designed so that the driving part such as a voice coil connected to diaphragm S may vibrate and radiate acoustic waves. The number of speakers in speaker array 10 is not limited to four but may be any number as long as it is plural. The connection method may be either a parallel connection or a series connection as long as it is a connection method to let the plural speakers be under the same condition. If the reflection surface of reflection unit 42 is planar as in the embodiment of FIGS. 1 and 2, the plural speakers 11 to 14 are arranged to form a circular arc shape so as to give an equal reflection path distance. Of course, the shape of the reflection surface of reflection unit 42 is not limited to a plane shape but may be a curved surface shape as long as speaker array 10 is constructed to give an equal reflection path distance as described above. Further, reflection unit 42 may be made of an acoustic reflection plate or an architecture plate member having a high reflectivity, and may be wall surface 103 of chamber 101.

[Embodiment 2]

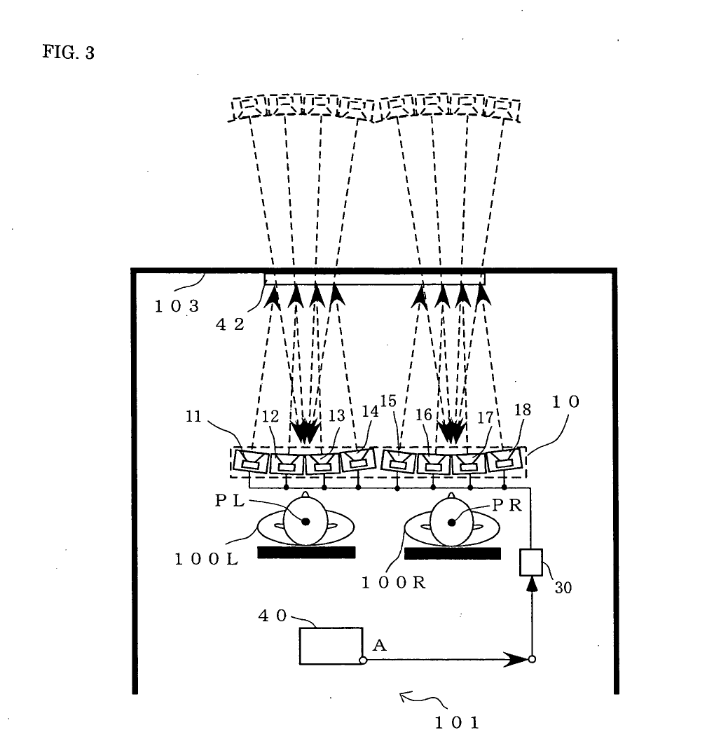

FIG. 3 is a plan view describing a reproduction system for an audio signal according to another preferable embodiment of the present invention. Two viewers/listeners 100L and 100R are arranged to the right and left in chamber 101. In the case of providing an audio signal A from speaker array 10 to viewer/listener 100L located at a listening point PL and to viewer/listener 100R located at a listening point PR, the plural speakers 11 to 18 in speaker array 10 are divided into two sets (11 to 14) and (15 to 18) corresponding to the two listening points PL and PR. Thus, in the reproduction system according to the present invention, even if there are plural viewers/listeners, speaker array 10 may be divided into plural sets of speakers and, by setting the direction and position of the speakers in each speaker set, each viewer/listener can obtain an audio image localization in the direction of reflection unit 42. Thus, the increase in the synthesized level of the reflected sounds at each of the listening points PL and PR can be easily made conspicuous, thereby eliminating the need for a large-scale delay circuit or level controlling means.

Here, the plural viewers/listeners are not limited to two persons as in this embodiment but may be three or more persons. Further, the number of speakers in speaker array 10 may be such that one set of speakers corresponding to one viewer/listener (one listening point) are plural.

[Embodiment 3]

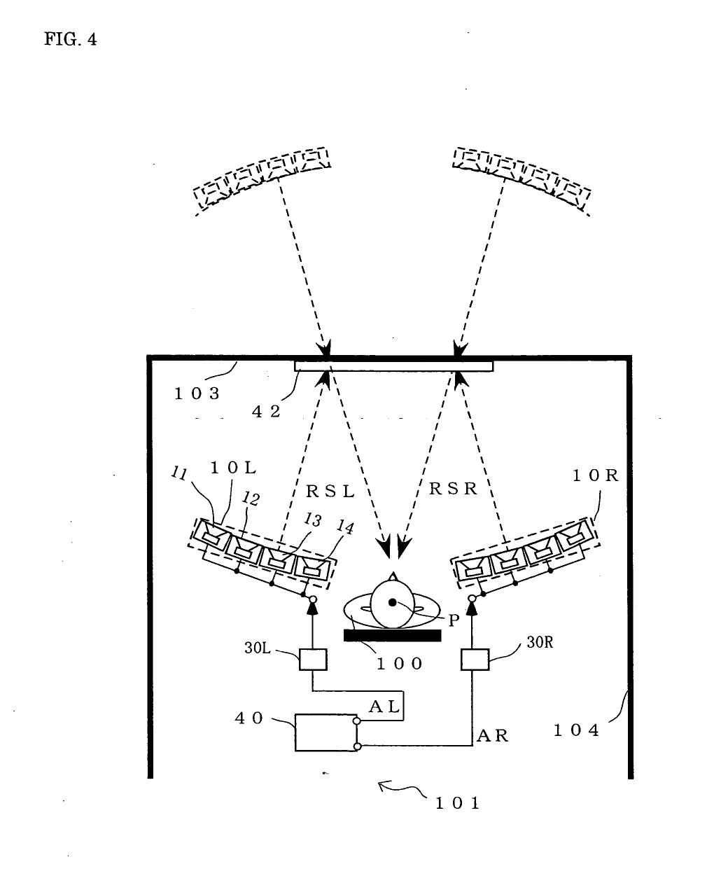

FIG. 4 is a plan view describing a reproduction system for an audio signal according to another preferable embodiment of the present invention. In the illustrated case, the audio signal reproduced from reproduction apparatus 40 is a stereo signal composed of a left audio signal AL and a right audio signal AR. Left audio signal AL passes through amplifier 30L to be input into speaker array 10L, and right audio signal AR passes through amplifier 30R to be input into speaker array 10R. Speaker arrays 10L and 10R are constructed with parallel connection of four speakers 11 to 14 and 15 to 18 having a diaphragm. Here, the vibration direction of the diaphragm of each speaker is directed towards reflection unit 42, and the reflection path distance from the diaphragm of each speaker to listening point P, which defines a position of viewer/listener 100, via a reflection surface of reflection unit 42 is set to be equal.

As a result of this, the radiated sounds radiated from speaker arrays 10L and 10R are reflected by reflection unit 42 and arrive at listening point P. For left audio signal AL, viewer/listener 100 can obtain an audio image localization in the front left direction along which the reflected sound RSL arrives. For right audio signal AR, viewer/listener 100 can obtain an audio image localization in the front right direction along which the reflected sound RSR arrives. Thus, since the reproduction system of the present invention includes speaker array and reflection unit corresponding to channel signals of an audio signal, the localization in the right and left directions can be easily realized by providing speaker array 10L and speaker array 10R.

Here, the audio signal is not limited to a monaural signal or a stereo signal. Even if the audio signal is a multi-channel surrounding signal including a side left signal and a side right signal, by providing reflection unit on side walls 104 located at the sides of viewer/listener 100 and providing speaker arrays (not illustrated) corresponding to these reflection unit on the ceiling, the viewer/listener can obtain an audio image localization of each channel signal in the direction of the reflection unit.

[Embodiment 4]

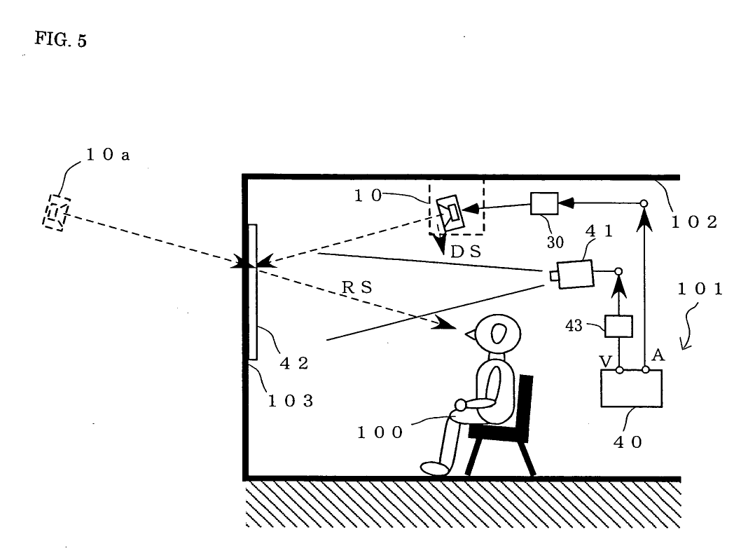

FIG. 5 is a side cross-sectional view describing a reproduction system for a video signal and an audio signal according to a preferable embodiment of the present invention. Audio signal A reproduced from reproduction apparatus 40 passes through amplifier 30 to be input into speaker array 10. Speaker array 10 is constructed with plural speakers having a diaphragm. The vibration direction of the diaphragm of each speaker is directed towards a screen 42 in which the reflection surface of the reflection unit and the projection surface are integrally constructed. The reflection path distance from the diaphragm of each speaker to listening point P, which defines a position of viewer/listener 100, via a reflection surface of screen 42 is set to be equal.

On the other hand, a video signal V reproduced from reproduction apparatus 40 passes through a video delay circuit 43 of the projection unit, and is projected by a projector 41 onto the projection surface of screen 42 disposed on wall surface 103 in the front. In addition, the delay time of the video delay circuit that delays the video signal is set to be approximately equal to the time required for an acoustic wave to propagate through the reflection path distance. This delay time is a period of time of about 2 to 9 msec, preferably about 3 to 5 msec, in accordance with the size of chamber 101, the distance from speaker array 10 to screen 42, and others. The video delay circuit may be any circuit such as a digital delay circuit. As a result of this, in reproducing synchronized video and audio signals, the video image localization coincides with the audio image localization in the front for viewer/listener 100, and no time lag is present between the reproduction of video images and the reproduction of audio images, so that there will be no reproduction state that gives viewer/listener 100 a sense of discordance.

Furthermore, if video signal V reproduced from reproduction apparatus 40 is delayed relative to synchronized audio signal A by video signal processing such as progressive scan, the delay time of the video delay circuit in the above-described embodiment may be obtained by subtracting the time required for video signal processing from the time required for an acoustic wave to propagate through the reflection path distance. Further, if the time required for video signal processing is extremely long and is longer than the time required for an acoustic wave to propagate through the reflection path distance, an audio delay circuit for delaying audio signal A may be provided in place of the video delay circuit that delays video signal V. Therefore, even if the time required for video signal processing of video signal V is long, one can eliminate the time lag between the reproduction of video images and the reproduction of audio images for the viewer/listener.

Here, the reproduction system for a video signal and an audio signal according to the present invention is not necessarily limited to the case in which the reflection surface of the reflection unit and the projection surface are integrally constructed as a screen. In the case of an audio channel signal in which the direction of the localization of the video images is not coincident with the direction of the localization of the audio images, reflection unit such as an acoustic reflection plate may be disposed in the direction for localizing the audio images, separately from the projection surface (screen) disposed in the front. The projection unit and the projection surface are not limited to a projector and a screen alone. Representatively, they may be a video displaying apparatus such as a cathode ray tube or a liquid crystal display and a projection surface thereof that can display a video signal.

In the reproduction system for video and audio signals according to the present invention, a reproduction state giving a sense of integration with coincident localizations of video images and audio images can be obtained easily and at a low cost even in a representative case of disposing a speaker array on a ceiling in a chamber. Further, a good reproduction with synchronized video and audio images can be made.

In the case of disposing a display or a screen on a wall surface in a chamber, the freedom of using the space in the chamber can be increased by disposing the speakers on a ceiling. At the same time, since the direction of projecting the video signal and the direction of the arriving audio signal are coincident, a reproduction state giving a sense of integration can be realized. The present invention can be applied not only to a case of using the reproduction system at home but also to a case of reproducing sounds to exhibited objects and video images in a museum, an exhibition hall, or the like.

1. A reproduction system for reproducing an audio signal to a viewer/listener in a chamber, said reproduction system comprising:
speaker array including plural speakers having a diaphragm for reproducing the audio signal; and
reflection unit disposed in the chamber, reflecting a radiated sound from the speaker array, wherein
the plural speakers of the speaker array are positioned so that
vibration direction of each diaphragm may be directed towards the reflection unit, and
reflection path distance from each diaphragm to a listening point, which defines a position of the viewer/listener, via a reflection surface of the reflection unit may be equal.

2. The reproduction system according to claim 1, wherein the plural speakers of the speaker array are divided into plural sets corresponding to plural listening points.

3. The reproduction system according to claim 1, comprising speaker array and reflection unit corresponding to channel signals of the audio signal.

4. The reproduction system according to claim 1 for reproducing synchronized video and audio signals to the viewer/listener in the chamber, further comprising projection unit projecting the video signal and a projection surface disposed in the chamber.

5. The reproduction system according to claim 4, wherein the reflection surface of said reflection unit and said projection surface are integrally constructed and disposed in said chamber.

6. The reproduction system according to claim 4, wherein said projection unit comprises a video delay circuit delaying said video signal projected onto said projection surface, and a delay time of the video delay circuit is set to be approximately equal to a time required for an acoustic wave to propagate through said reflection path distance.

7. The reproduction system according to claim 4, further comprising a video delay circuit delaying said video signal or an audio delay circuit delaying said audio signal, and a delay time of the video delay circuit or the audio delay circuit is set to maintain synchronization of the video signal and the audio signal in accordance with a time required for processing the video signal and a time required for an acoustic wave to propagate through said reflection path distance.
